(19) United States
(12) Patent Application Publication
(10) Pub. No.: US 2025/0299932 A1
(43) Pub. Date: Sep. 25, 2025

(54) VERTICAL FASTENER ASSEMBLY FOR COUPLING AN UPPER ELECTRODE OF A PLASMA CHAMBER

(71) Applicant: VM Inc., Icheon-si (KR)

(72) Inventors: Hwi Gon JANG, Yongin-si (KR); Woo Hyung CHOI, Seongnam-si (KR); Jin Myeong LEE, Yongin-si (KR); Sung Hwan PARK, Suwon-si (KR)

(21) Appl. No.: 19/037,746

(22) Filed: Jan. 27, 2025

(30) Foreign Application Priority Data
Mar. 21, 2024 (KR) 10-2024-0039180

(51) Int. Cl. H01J 37/32

(52) U.S. Cl. CPC H01J 37/32568

(57) ABSTRACT

A vertical fastener assembly for coupling an upper electrode of a plasma chamber comprises a vertical shaft extending in a vertical direction and coupled to the upper plate; a rotating unit coupled to an upper part of the vertical shaft and moving the vertical shaft up and down; a stress releasing pin coupled to the upper electrode and coupled to the vertical shaft in a removal way; an elastic unit coupled to a lower part of the stress releasing pin; and a pin housing coupled to an upper part of the stress releasing pin.

### BACKGROUND OF THE INVENTION

### Field of the Invention

The present invention relates to a vertical fastener assembly for coupling an upper electrode of a plasma chamber, specifically the vertical fastener assembly to couple the upper electrode to an upper plate of the plasma chamber in a vertical direction.

### Description of the Related Art

In case of the upper electrode of the plasma chamber, when a threaded portion formed directly is fastened by a bolt, then the threaded portion of the bolt fastening portion may be damaged due to a fastening force of the bolt. And also, a gap between the electrode and the plate may be created by a loosening of the bolt fastening due to a chamber property with a large temperature change to reduce a performance of an etching process and at the same time to generate a fall risk. Therefore, a fastener assembly needs to be developed for fastening the upper electrode of the plasma chamber in a simple structure, maintaining or repairing easily, obtaining a performance of the etching process by a uniform lifting, absorbing heat stress and preventing a fall. The prior art has a structure that a connecting member extends in a diameter for clamping, thus the prior art has a disadvantage that it is impossible to fasten in a vertical direction. And also, if a loosening or a deformation of the coupling part due to a thermal stress happens at a vacuum plasma chamber in an environment of a rapid temperature change, it has a disadvantage that not only a performance of an etching process is degraded but also a fall hazard exists. And also, a frequent cleaning and an exchanging period acts as a very important factor in case of the vacuum plasma chamber because various processes may be carried out within the chamber and a problem that by-products according to the processes may get caught between structures to have a negative impact. The prior art has a disadvantage that it cannot solve such problems and it has a difficulty in a maintenance.

The present invention is intended to solve the problems of the prior art and has the following purposes.

### PURPOSE OF THE INVENTION

The object of the present invention is to provide with a vertical fastener assembly for coupling an upper electrode of a plasma chamber in order to deal with various deformations by fastening the upper electrode to the upper plate in a vertical direction.

### SUMMARY OF THE INVENTION

In one embodiment of the present invention, a vertical fastener assembly for coupling an upper electrode of a plasma chamber comprises a vertical shaft extending in a vertical direction and coupled to the upper plate; a rotating unit coupled to an upper part of the vertical shaft and moving the vertical shaft up and down; a stress releasing pin coupled to the upper electrode and coupled to the vertical shaft in a removal way; an elastic unit coupled to a lower part of the stress releasing pin; and a pin housing coupled to an upper part of the stress releasing pin.

In other embodiment of the present invention, the vertical shaft comprises a coupling part with a cylindrical shape and a coupling hole formed in a direction vertical to an extending direction of the coupling part, and a coupling tap formed at an upper part of the stress releasing pin, and the coupling tap formed at the upper part of the stress releasing pin is coupled to the coupling part in a removal way.

In another embodiment of the present invention, the elastic unit has a coil shape and the elastic unit is coupled to the stress releasing pin in a way that the stress releasing pin penetrates the elastic unit.

In still another embodiment of the present invention, the vertical shaft comprises a center block; and an inserting coupling part extending above the center block and coupled to the rotating unit, and a rotation limiting part is formed at the center block.

In still another embodiment of the present invention, an up and down movement of the stress releasing pin is guided by the elastic unit.

In still another embodiment of the present invention, a direction of the vertical shaft is changed or the vertical shaft moves up and down by the rotation of the rotating unit.

In still another embodiment of the present invention, the vertical fastener assembly comprises a separation preventing ring unit coupled to an upper part of the rotating unit and preventing the rotating unit from being separated.

### BRIEF DESCRIPTION OF THE DRAWINGS

FIG. 1 shows an embodiment of a vertical fastener assembly for fastening an upper electrode of a plasma chamber according to the present invention.

FIG. 2 shows an embodiment of a state where the upper electrode is fastened to the upper plate by the vertical fastener assembly according to the present invention.

FIG. 3 shows an embodiment of a process to fasten the upper electrode to the upper plate by the vertical fastener assembly according to the present invention.

FIG. 4 shows an embodiment of an upper fastener forming the vertical fastener assembly according to the present invention.

FIG. 5 shows another embodiment of the vertical fastener assembly according to the present invention.

### DETAILED DESCRIPTION OF EXEMPLARY EMBODIMENTS

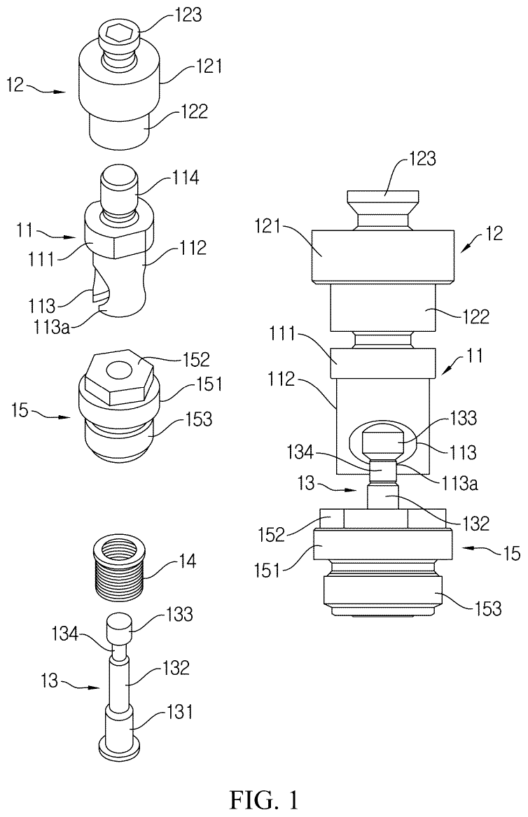

FIG. 1 shows an embodiment of a vertical fastener assembly for fastening an upper electrode of a plasma chamber according to the present invention.

Referring FIG. 1, a vertical fastener assembly for coupling an upper electrode of a plasma chamber comprises a vertical shaft 11 extending in a vertical direction and coupled to the upper plate; a rotating unit 12 coupled to an upper part of the vertical shaft 11 and moving the vertical shaft 11 up and down; a stress releasing pin 13 coupled to the upper electrode and coupled to the vertical shaft 11 in a removal way; an elastic unit 14 coupled to a lower part of the stress releasing pin 13; and a pin housing 15 coupled to an upper part of the stress releasing pin 13.

The vertical fastener assembly may consist an upper fastener coupled to the upper plate and a lower fastener coupled to the upper electrode combined to a lower part of the upper plate, and if the lower fastener is coupled to the upper fastener, then the upper electrode would be coupled to the upper plate. The upper fastener comprises the vertical shaft 11 extending vertically and coupled to the upper plate; and a rotating unit 12 coupled to the upper part of the vertical shaft 11 to move the vertical shaft 11 up and down. And the lower fastener comprises the stress releasing pin 13 coupled to the vertical shaft in a removal way; the elastic unit 14 coupled to the lower part of the stress releasing pin 13; and the pin housing 15 coupled to the upper part of the stress releasing pin 13.

The vertical shaft 11 comprises a center block 111; a coupling part 112 extending in a downward direction of the center block 111 and having a cylindrical shape; a coupling hole 113 formed in a direction vertical to an extending direction of the coupling part 112; and an insertion coupling part 114 extending in an upward direction of the center block 111. The vertical shaft 11 may be coupled in a way to penetrate an edge part of the upper plate, and can move up and down by the rotating unit 12. The center block 111 may have a shape where facing parts of a circular plate with a constant thickness are cut. Hence, the center block 111 may comprise two parts formed by facing two arcs of a circle and two parts formed by two lines extending in a parallel way each other. The facing two parts formed by two straight lines may make a rotation limiting parts.

A connecting node with a cylindrical shape may be formed in an upward direction of the center block 111, and the inserting coupling part 114 with a cylindrical shape may extend in an upward direction of the connecting node. The inserting coupling part 114 may be inserted with the rotating unit 12 to be coupled, and hereby, the vertical shaft 11 may be coupled to the rotating unit 12. The coupling part 112 with a cylindrical shape on the whole may be formed at the center block 111, and the coupling hole 113 may be formed at the lower part of the coupling part in a direction vertical to the extending direction of the coupling part 112. The coupling hole 113 may become a cylindrical shape, and an inserting gap may be formed at the lower part of the coupling part 113. The coupling hole 113 may be form in a way to penetrate the lower part of the coupling part 112, hereby the coupling hole 113 may have a shape where facing both sides are open. And the inserting gap 113a may have a structure where the lower end part of the coupling part 12 is cut with a constant width along a diameter direction. Hereby, the lower part of the coupling hole 113 may be connected to the upper part of the inserting gap 113a, and a passage capable of being connected to the outside may be formed at the lower part of the coupling part 112.

The rotating unit 12 may comprise a rotating body 121 having a cylindrical shape; a coupling cylinder 122 extending in a downward direction of the rotating body 112 with a hollow cylindrical shape in order that the inserting the inserting coupling part 114 can be inserted; and a coupling tap 123 extending in the upward direction of the rotating body 121. The coupling tap 123 may have various structures capable of being rotated by various rotating tools, and the rotating unit 12 may be rotated by the rotation of the coupling tap 123, and thereby, the vertical shaft 11 may move up and down. The rotating unit 12 or the vertical shaft 11 coupled to the rotating unit 12 may move up and down in various ways, but not limited to.

The stress releasing pin 13 may comprise a lower body 131 having a cylindrical shape; a fixing member 132 having a diameter smaller than that of the lower body 131 and extending in the upward direction from the upper end of the lower body 131 with a cylindrical shape; a node member 134 extending from the fixing member 131 and having a relatively small diameter; and a coupling tap 133 extending from the node member 134, having a size capable of being received within the coupling hole 133 and having a cylindrical shape. The elastic unit 14 having a coil spring shape may be coupled to the fixing member 132, and the stress releasing pin 13 may be coupled to the pin housing 15 in a way to penetrate the pin housing 15.

The pin housing 15 may comprise a housing body 151 with a cylindrical shape; fixing coupling block 152 having a polygonal nut shape and coupled to the upper part of the housing body 151; and a guiding block 153 extending in the downward direction of the housing body 151. If the elastic unit 14 is coupled to the stress releasing pin 13, then the stress releasing pin 13 may be received within a coupling hole formed along the longitudinal direction of the pin housing 15 for coupling. The upper part of the fixing member 132, the node member 134 and the coupling tap 133 may protrude upward from the pin housing 15, then the node member 134 would be located at the inserting gap 113a, and the coupling tap 133 would be located within the coupling hole 113. Thereby, the upper electrode may be coupled detachably to the upper plate.

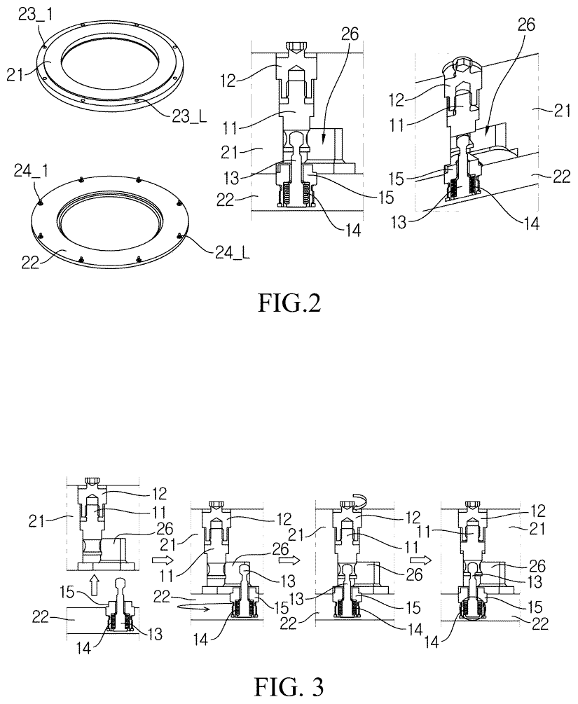

FIG. 2 shows an embodiment of a state where the upper electrode is fastened to the upper plate by the vertical fastener assembly according to the present invention.

Referring to FIG. 2, the upper plate 21 may have a circular strip shape extending with a constant width and along a circumference of a circle, and a plurality of coupling holes may be formed along the circular edge. And each upper fastener 23_1 to 23_L may be coupled each coupling hole.

The upper electrode 22 coupled to the lower part of the upper plate 21 may have a shape similar to the upper plate 21, for example, may have a circular strip shape. A plurality of combining holes may be formed along the circular edge of the upper electrode 22, and each lower fastener 24_1 to 24_L may be coupled to each combining hole. The number of the combining holes may be the same as that of the coupling holes and the combining holes may be formed at positions corresponding to those of the coupling holes. As each lower fastener 24_1 to 24_L is coupled to each upper fastener, the upper electrode 22 may be coupled to the upper plate 21.

As shown in middle part and right part of FIG. 2, the lower fastener may be coupled to the upper fastener within a coupling groove 26. The coupling groove 26 may be formed at a position where the upper plate 21 contacts the upper electrode, and the coupling groove 26 may be formed in a way extending along the circumference of the upper plate 12. The vertical shaft 11 and the rotating unit 12 coupled to the upper part of the vertical shaft 11 may be coupled in a way to penetrate the upper plate from the upper surface to the lower surface.

The stress releasing pin 13 may extend upward from the upper electrode 22, and may protrude within the upper plate 21 to be coupled to the vertical shaft 11. And the pin house 15 may be located at a boundary surface of the upper plate 21 and the upper electrode 22. In a state that the upper fastener and the lower fastener are coupled previously to the upper plate 21 and the upper electrode 22, respectively, the stress releasing pin 13 may be coupled to the vertical shaft 11 to couple the upper electrode 22 to the upper plate 21. If the upper electrode 22 is coupled to the upper plate 21 in this way, then the deformation due to a heat or an impact may be absorbed by the elastic unit 14. And also, an assembling easiness and a maintenance efficiency may be enhanced by coupling the fastener assembly in a vertical direction.

FIG. 3 shows an embodiment of a process to fasten the upper electrode to the upper plate by the vertical fastener assembly according to the present invention.

Referring to FIG. 3, the upper fastener, including the vertical shaft 11 and the rotating unit 12 coupled to the upper part of the vertical shaft 11 and moving the vertical shaft 11 up and down, may be coupled to the upper plate 21. The coupling groove 26 may be formed at the upper plate 21, and the coupling groove 26 may be formed at the lower part of the upper plate 21 and may extend along a circumferential direction.

The lower fastener, which the elastic unit 12 is coupled to and having a structure in which the stress releasing pin 13 is received in the pin housing 15, may be coupled to the upper electrode 22 in a way to penetrate the upper electrode 22 from bottom to top. The stress releasing pin 13 may protrude upward from the upper electrode 22, and the upper part of the pin housing 15 may protrude upward from the upper electrode 22. The lower surface of the upper plate 21 may contact the upper surface of the upper electrode 22, and the lower surface of the upper plate 21 and the upper surface of the upper electrode 22 may contact each other based on the coupling positions of the upper fastener and the lower fastener.

As the upper plate 21 contacts the upper electrode 22, the upper part of the stress releasing pin 13 may be located at the coupling groove 26. And also, the vertical shaft 11 and the stress releasing pin 13 may be located on a concentric circle. In this condition, the upper electrode 22 may rotate based on a center, and the coupling tap of the stress releasing pin 13 may be received within the coupling hole of the vertical shaft 11 for coupling the upper fastener to the lower fastener each other. In this coupling condition, if the rotating unit 12 is rotated, then the vertical shaft may move upward to apply a pressure to the stress releasing pin 13. Thereby, the elastic is compressed to lift upward from the upper electrode 22 for contacting the upper plate 21 closely. The plurality of upper fasteners coupled to the upper plate 21 may be coupled to the plurality of lower fasteners coupled to the upper electrode 22 each other, as discussed above, and each upper fastener and each lower fastener are mounted in an identical torque and the coupling state may be maintained by a uniform force. Thereby, the coupling stability may be enhanced.

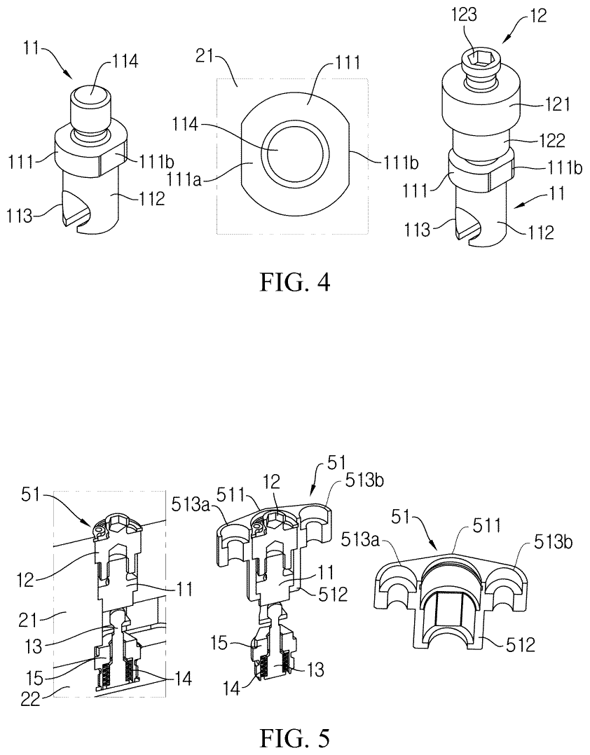

FIG. 4 shows an embodiment of an upper fastener forming the vertical fastener assembly according to the present invention.

Referring to FIG. 4, rotation limiting parts 111a, 111b may be formed at the facing positions of the center block 11 of the vertical shaft 11. The center block 111 may have a constant thickness and may comprise a circumferential portions extending in a circle and peripheral portions extending in a straight line. And the peripheral portions formed at facing positions and extending in the straight line may become the rotation limiting parts 111a, 111b. Therefore, the center block 111 may comprise the rotation limiting parts 111a, 111b located at the facing positions and extending in a parallel shape and are peripheral parts connecting different rotation limiting parts 111a, 111b.

The coupling cylinder 122 having a diameter smaller than that of the rotating body 121 with a cylindrical shape may be formed at the lower part of the rotating body 121, and the coupling tab 123 may be formed at the upper surface of the rotating body 121. The insertion coupling part 114 may be inserted within the coupling cylinder 122 for coupling, and the center block where the rotation limiting parts 111a, 111b are formed may be located at the lower part of the insertion coupling part 114. The vertical shaft 11 may move up and down by rotation of the rotating unit 12, and thereby the center block 11 may move up and down. If the center is moved to a predetermined position, then the rotation of the rotating unit 111 may be limited due to the structure of the rotation limiting parts 111a, 111b, and accordingly the upper fastener or the vertical shaft 11 may be fixed at the predetermined position to maintain the coupling state stably. The rotation limiting parts 111a, 111b may have various structures to limit the rotation of the center block 111, but not limited to.

FIG. 5 shows another embodiment of the vertical fastener assembly according to the present invention.

Referring to FIG. 5, the fastener assembly further comprises a separation preventing ring 51 coupled to the upper part of the rotating unit 12 for preventing a separation of the rotating unit 12. The upper fastener may have a shape to penetrate the upper plate from top to bottom, and it is necessary for the upper fastener to be fixed stably at the upper plate. For example, various kinds of fastening rings or elastic means may be used for preventing the upper fastener from being loosened owing to an external vibration, an impact or a thermal change or the like. And also, a fixing means with a suitable structure may be applied for preventing the coupling means from being separated. Specifically, the separation preventing ring 51 may be coupled at the upper part of the rotating unit 12 for preventing the rotating unit 12 from being separated.

The separation preventing ring 51 may comprise a ring body 511 for receiving the vertical shaft 11 and the rotating unit 12; a receiving body 512 extending with a cylindrical shape and downward from the ring body 511; and fixing wings 513a, 513b extending to both sides of the ring body 511. The receiving body 12 may become a cylindrical shape with a diameter smaller than that of the ring body 511, and a step surface may be formed at the boundary between the ring body 511 and the receiving body 512. And also, each of fixing wings 513a, 513b may have a cylindrical shape, and a step surface may be formed within each fixing wing 513a, 513b. A portion of the rotating unit 12 and the vertical shaft 11 may be received within the ring body 511 and the receiving body 512, and each fixing wing 513a, 513b may be fixed at the upper plate to prevent the upper fastener from be separated. Various type of C-rings or O-rings may be applied to the upper fastener or the lower fastener, but not limited to.

What is claimed is:

1. A vertical fastener assembly for coupling an upper electrode of a plasma chamber comprising:
a vertical shaft extending in a vertical direction and coupled to the upper plate;
a rotating unit coupled to an upper part of the vertical shaft and moving the vertical shaft up and down;
a stress releasing pin coupled to the upper electrode and coupled to the vertical shaft in a removal way;
an elastic unit coupled to a lower part of the stress releasing pin; and
a pin housing coupled to an upper part of the stress releasing pin.

2. The vertical fastener assembly according to claim 1, wherein the vertical shaft comprises a coupling part with a cylindrical shape and a coupling hole formed in a direction vertical to an extending direction of the coupling part, and a coupling tap formed at an upper part of the stress releasing pin, and the coupling tap formed at the upper part of the stress releasing pin is coupled to the coupling part in a removal way.

3. The vertical fastener assembly according to claim 1, wherein the elastic unit has a coil shape and the elastic unit is coupled to the stress releasing pin in a way that the stress releasing pin penetrates the elastic unit 14.

4. The vertical fastener assembly according to claim 1, wherein the vertical shaft comprises a center block; and an inserting coupling part extending above the center block and coupled to the rotating unit, and a rotation limiting part is formed at the center block.

5. The vertical fastener assembly according to claim 1, wherein an up and down movement of the stress releasing pin is guided by the elastic unit.

6. The vertical fastener assembly according to claim 1, wherein a direction of the vertical shaft is changed or the vertical shaft moves up and down by the rotation of the rotating unit.

7. The vertical fastener assembly according to claim 1, wherein the vertical fastener assembly comprises a separation preventing ring unit coupled to an upper part of the rotating unit and preventing the rotating unit from being separated.
